(19) United States
(12) Patent Application Publication
(10) Pub. No.: US 2003/0108098 A1
(43) Pub. Date: Jun. 12, 2003

(54) Pulse width modulated controller

(76) Inventor: Earl Russell Geddes, Northville, MI (US)

Correspondence Address: Earl R. Geddes, 43516 Scenic Lane, Northville, MI, 48167, US

(21) Appl. No.: 10/251,252

(22) Filed: Sep. 20, 2002

Related U.S. Application Data
(63) Continuation-in-part of application No. 09/939,148, filed on Aug. 24, 2001.

(51) Int. Cl. H03K 7/08; H03K 9/08

(52) U.S. Cl. 375/238; 332/109

(57) ABSTRACT

A Pulse Width Modulated power amplifier which has a random or pseudo-random comparator switching mechanism for reduced distortion and radiated RF emissions is disclosed.

### BACKGROUND

1. Field of the Invention

The present invention relates to a method for creating a Pulse Width Modulated (PWM) control signal as used in a variety of signal processing and control situations from an analog signal input or a digital representation of that signal (Pulse Code Modulation). Specific embodiments include PWM amplifiers for audio and PWM motor controllers.

2. Description of Prior Art

Pulse width modulation (PWM) is a technique for converting an analog signal into a binary signal. In the binary signal the information is carried via the width of the “pulse” whose height varies between the binary states of “1” and “0” or alternatively “on” and “off”. Much prior art exists for performing this conversion, but suffice it to say, the vast majority are founded in the block diagram as shown in FIG. 1. A good review of PWM technology can be found in PWM from Apex MicroTechnology Corp. as an Internet download. The input is any “band limited” signal. “Band limited” here means that the input signal does not have any frequency content above one half of the sampling frequency—the so called Nyquist frequency. The input 5 is fed to a comparator 10 whose output is either a high state or a low state depending on whether or not the input signal, at any point in time, is greater than or less than the comparison waveform 15. The comparison waveform can be of several varieties but the most common, also shown in FIG. 1, is a so-called saw tooth waveform. The output of the comparator will then be a pulse width modulated signal 20. Note that the PWM signal is binary since the output state contains only two levels, high and low (one and zero or one and minus one in the curves shown in this application, although, in practice, these levels can be of any values).

To show how the nature of the original input signal has been retained in the PWM output consider the spectrum of the output signal as shown in FIG. 2 for an input signal composed of a single 1024 Hz. sine wave. This spectrum contains the original signal (the lowest peak) but it also contains a multitude of spurious peaks at very high frequencies, the switching frequency signal, or carrier, as well as some distortion products, many of which lie within the desired passband of the input signal. If these upper frequencies are filtered out, typically at some fraction of the sampling frequency, then a reasonable facsimile of the original signal can be recovered.

The uses for this technique are numerous. An example is shown in FIG. 3 where the PWM signal drives a transistor 30, usually of the MOSFET variety, which is connected between a supply voltage 40 and a load 50 that is connected to ground or another supply voltage. The signal current through the load will be that of the PWM waveform. If the upper frequencies are either blocked or shunted (filtered) so that they do not go through the load then the signal seen by the load is an accurate reproduction of the input signal except at a much higher power level. Hence a controller/amplifier can be created with the characteristic that the output transistor(s) is(are) either in an on state or an off state and nothing in between. This results in a very efficient transfer of power to the load since no power is dissipated in the control device itself.

PWM techniques are used in power amplifiers for audio systems, motor controllers and other high power control systems in order to simplify or lower the design requirements of the device (mostly due to lower thermal dissipation in the high power drive circuit).

There are several disadvantages of the controller/amplifier as shown here. First is the fact that the high frequency artifacts can be very high in frequency. For example, in an audio amplifier the bandwidth should go to 20_kHz. A rule of thumb for a good PWM amplifier is that the sampling frequency should be ten times greater than the upper bandwidth required. This is because the artifacts go well below the sampling frequency and can thus lie within the desired passband unless the sampling frequency is much higher than the Nyquist frequency. These artifacts are clearly visible in FIG. 2. This places the desired sample rate at about 200 kHz with harmonics that go well into the megahertz region. At these frequencies the actual circuit components, the load and the associated wiring can become very efficient radiators (antennas) with the end result that the amplifier will generate a substantial amount of Radio Frequency Interference (RFI). Historically, these problems have severely limited the use of PWM amplifiers in applications such as automotive where the lower heat dissipation and the higher efficiency would be tremendous benefits but the RFI problems are prohibitive.

Another problem with classical PWM designs is distortion. PWM controllers built with conventional comparison waveforms suffer from severe distortion problems that result from an incorrect output switching time the comparator. The comparison and input waveforms cross and the comparator's output switches at a point in time which is not the actual point where this should occur for a linear output. This problem is well know and there are several ways to correct it.

First method is to “adjust” the switching point so that it occurs at the correct time. This approach is computationally intensive and for that reason is not often used. The second is through the use of feedback. However, since the output of the amplifier is not a pure analog signal, feedback can be problematic. There are many solutions to the feedback problem. For example, in 1998 Tripathi et al, in U.S. Pat. No. 5,777,512 (which is also a good reference for PWM technology in general) disclosed a method for creating feedback that is both analog and digital in nature. Virtually all other forms of feedback are subsets of the technique disclosed therein.

The techniques of Tripathi were further extended in 2001 and applied to a PWM amplifier in U.S. Pat. No. 6,229,390. The PWM forming circuitry is that of U.S. Pat. No. 5,777,512.

In 1997 Adrian et al. disclosed in U.S. Pat. No. 5,617,058, “Digital Signal Processing for Linearization of Small Input Signals To a Tri-State Power Switch”, a method for minimizing distortion in a tri-state device using DSP techniques. It also shows a mechanism for reducing the high frequency energy delivered to the load and hence the associated EMI. This patent is significant in that it shows how a direct digital Pulse Code Modulated (PCM) signal can be used as the input to the amplifier. Its techniques are specific to tri-state implementation.

In 2002 Horigan disclosed in U.S. Pat. No. 6,384,651, “Method of Generating a Signal with Controlled Duty-cycle and Pseudo-random Spectrum”, a method for spreading the sound spectrum generated by the switching cycles of the power applied to a laptop computer. This patent is significant in that it uses a random witching rate with a constant average in order to reduce the spectral components of radiated audible noise. This is similar to the invention disclosed here except that it is RF noise being generated electrically by a power amplifier of audio signals.

All of the prior art suffers from one or more of the following problems:

EMI from the high frequency switching content of the output signal

Non-linear distortion products in the desired passband of the output signal

Complex calculations and/or circuitry required to overcome these deficiencies

### OBJECTS AND ADVANTAGES

The object of this patent application is to disclose an alternate method for converting an analog signal or PCM signal into a PWM signal. It is a further object of this application to disclose additional improvements in a controller/amplifier that uses this technique, which can be achieved with little or no additional effort once the comparison waveform generation means have been implemented. These new techniques result in lower distortion, lower peak levels of RF radiation and better perceived sound quality (in the case of an audio amplifier). These can all be achieved with through simple modifications to the comparison waveform as described herein.

In order to function in a linear manner the comparison waveform must have straight (linear) sections that extend from the high state to the low state and visa-versa. The exact details of the how and when this transition occurs are not important only that for linear output this transition must be linear between the two states. Conventional means can use very simple circuits to generate a saw tooth waveform as the comparison waveform input to the comparator. If on the other hand the waveform were to switch states in a random manner while still maintaining straight lines through the state transitions then several important improvements are evident.

FIG. 4 shows an example of this type of waveform. When used as the comparison waveform to the comparator the output of the comparator will be as shown in FIG. 5. This waveform is still a binary PWM signal and the original signal can still be replicated by filtering out the high frequency components, just as in the prior art, but now the carrier is random, i.e. noise. The spectrum of the output signal, shown in FIG. 6, shows a significant improvement in distortion and a considerable lowering of the high frequency peaks. In other words the spectral energy of the carrier is both spread and randomized by the use of a randomly switched waveform while simultaneously improving the linearity of the transfer function. The improved linearity results because the errors in the time estimates of the switching, as described above, have been randomized and made incoherent by the random nature of the sampling.

Other techniques can be used to “spread” the spectrum of the switching frequency, for example by frequency modulating the carrier. This does spread the spectrum and lower the switching frequency peaks, however, it can be shown that randomly switching the states will spread the spectrum to the lowest possible level given the constraints of a maximum switching frequency and the desire to not have switching noise in the pass band.

The minimum switching period will determine the frequency at which the high frequency energy will begin to fall off and the longest period will determine the lower frequency of this spread. The energy is spread between these two frequencies.

Unlike the periodic saw tooth waveform, the generation of a random waveform, shown in FIG. 4, is not as straightforward as with traditional analog techniques. However, in these days of high speed and low cost Digital Signal Processors (DSP), generating this waveform digitally is a trivial matter. Thus, in a preferred embodiment the invention disclosed herein would have some form of DSP control circuitry 60 as shown in FIG. 7. A Digital to Analog (D/A) converter 70 may also be required.

Generation of the random waveform could follow along several different lines. The waveform could be stored in ROM, being generated off-line. Or a simple table of random numbers could be stored. The algorithm would then simply read through the table of numbers and interpolate the required straight line section using the random number as the number of samples in the period or half period of the cycle. Random numbers could also be generated on the fly being either fully random or pseudo-random in nature. The easiest method of generating a random transitioning signal is by generating a Maximum Length Sequence (MLS) and interpolating straight lines between each transition of the MLS signal. In those techniques where the number obtained [the random number, which] is an integer, which lies between some fixed lower integer (usually one) and some fixed upper integer, this number represents the number of DSP cycles in the period of the current comparison waveform section. The DSP circuit is thus running at a rate substantially higher than the Nyquist frequency for the input signal.

It is important to note that the properties of the random waveform are very important. If the transition times of the waveform are not truly random, i.e. has an auto-correlation or auto-correlation sequence substantially different from unity, then the generated carrier noise signal will also not be truly random. A truly random carrier noise is the most desirable. A pseudo-periodic random waveform will also not spread the spectrum as far as is possible with a purely random waveform since the period of the switcher will cause a lower limit on the carrier noise spectrum. Thus for a pseudo-random waveform a MLS is preferred since it has the narrowest auto-correlation sequence of any pseudo-random binary signal and is easily generated.

The comparison waveform can be a full period or a half period as required. It can also always have a waveform slope that is always positive or always negative, returning to the other state “instantaneously”. This later waveform would have the disadvantage of having more high frequency content in the output of the controller.

Another form of the preferred embodiment is shown in FIG. 8. In this embodiment the comparator is a coded function, i.e. an “if . . . then” statement or other DSP code which performs the comparator function. For example, at each sample, if the input PCM number is greater than the number created from the comparison waveform generator at that same sample then the code outputs a “high” state, otherwise the code outputs a “low” state. In this way the input signal can be a PCM signal representation of an analog signal. The D/A converter 70 can thus be eliminated. The controller as described in this embodiment is entirely digital with no analog components or paths.

Once one has placed a DSP control circuit in the controller/amplifier, the comparison waveform can be shaped in other useful ways. In order to understand these potential benefits I must digress.

Consider a PWM amplifier intended to be used in an audio system. Classic amplifier designs nearly all suffer from the characteristic that the harmonic distortion, as a percent, tends to increase as the signal level is decreased. This is particularly true of a conventional PWM amplifier of the type discussed herein. Because of masking effects in the human auditory system, perceptually this is exactly the wrong situation. The spread of masking increases substantially as the level of the sound is increased. This has the effect of masking out those distortion components that lie near to the original signal. The so-called order of the non-linearity, i.e. squared, cubic, etc. (referring to the power of the polynomial used to define the transfer characteristics of the non-linear system) is thus very important since in general, lower orders have distortion products which lie closer to the signals that generate them. The ears masking characteristics will then tend to mask the lower order non-linearities more than the higher orders and it will do so at an ever-increasing rate with sound pressure level. This means, in effect, that an amplifier whose distortion is composed of lower order components will not have audible artifacts if the distortion increases with level at a gradual rate. This is, as stated above, in stark contrast to the usual characteristic of amplifiers.

Another advantage that comes from the masking effect described above has to do with the “perceived” amplifier power and “sound quality”. In subjective studies, when subjects are asked to compare the “sound quality” and “power” for two amplifiers of equal output voltage swing, one with normal hard clipping characteristics and one with gradual soft clipping characteristics, they unanimously choose the soft clipping amplifier as sounding “cleaner” and more “powerful”. This occurred even though the soft clipped amplifier had harmonic distortion percentages that were higher than the hard clipped version at any output level below clipping. From the above discussion, the reason for this is obvious. The soft clipped waveform had predominately low order distortion components that increased gradually with level thus being completely masked by the auditory system. On the other hand the hard clipped amplifier had very little distortion at high levels, which is of no consequence, until it reaches the clipping stage at which point the distortion rises very quickly with very high order components.

The comparison waveform required to achieve this soft clipping characteristic is easy to generate with DSP using the following algorithm. If the comparison waveform is multiplied by a function

F(x)=a*x+b*x³+c*x⁵

where x is the current value of the comparison waveform and a is set such that this polynomial does not exceed one when x is equal to one, i.e. a+b+c=1.

With this comparison waveform the PWM generators transfer characteristic will be:

−c*\sqrt{10}(E*ATAN(c*x*\sqrt{10}/D)+D*ATANH(c*x*\sqrt{10}/E))/(F*D*E)

where

F=\sqrt{(9*b²−20*a*c)}

E=\sqrt{(−3*b+c*F)}

D=\sqrt{(3*b+c*F)}

An example of the multiplication factor F(x) and the corresponding transfer function are shown in FIG. 8 for the values a=0.5, b=0.25 and c=0.25. The transfer characteristic that results from this multiplication factor is shown in FIG. 8a, where the soft clipping characteristic is evident. The transfer characteristic exceeding 1.0 is of no concern since this simply means that the soft clipped amplifier will have a little more gain for small signals, but no more actual voltage swing capability than the hard clipped amplifier.

Thus I have shown how a PWM amplifier with a modified comparison waveform can have lower EMI problems, better sound quality at lower output level because of reduced distortion and better sound quality at high levels because of soft clipping. Perceptually this new amplifier will sound “louder” and “cleaner” than any of its predecessors. I have also shown how the power dissipated in the load versus the output devices can be manipulated at will. This can all be achieved with a simple DSP control circuit which modifies the comparison waveform is very simple ways.

Among the objects and advantages of the present invention are:

a) To reduce radiated RF signal peaks

b) To lower distortion products, mostly at lower output levels.

c) To provide for a mechanism through which an amplifier can have the characteristic that its distortion increases with level at a gradual rate.

Other objects and advantages will be evident to those skilled in the art.

### DRAWING FIGURES

FIG. 1 shows a block diagram of a circuit for creating a Pulse Width Modulation signal from an analog input signal;

FIG. 2 shows the spectrum of the signal found at the output of the PWM converter;

FIG. 3 shows an example of the use of a PWM converter in an application;

FIG. 4 shows an example of a random switching comparison waveform;

FIG. 5 shows the PWM output from a PWM converter that uses a random switching comparison waveform;

FIG. 6 shows the spectrum found of the signal found at the output of a PWM converter that uses a random switching comparison waveform;

FIG. 7 shows a preferred embodiment of a PWM controller/amplifier with a DSP control scheme for modifying the comparison waveform used in the comparator.;

FIG. 8 shows a preferred embodiment of a PWM controller/amplifier with a DSP control scheme that has the comparator function performed in code and uses a PCM signal as input;

FIG. 9a shows the multiplication factor to be applied to the comparison waveform in order to generate the non-linear transfer function found in FIG. 9b.

Reference Numerals in Drawings

```
  5 input waveform
10 comparator
15 comparison waveform
20 PWM output waveform
30 output switching transistor
40 supply voltage
50 load
60 DSP controller for generating comparison
    waveform
70 Digital to Analog converter
80 Pulse Code Modulated input signal
```

### SUMMARY

In accordance with the present invention, a method of generating a PWM waveform for a controller is disclosed wherein said waveform is such that the high frequency peaks in the output are reduced, the distortion in the output is reduced, and the controller can exhibit soft clipping characteristics if desired.

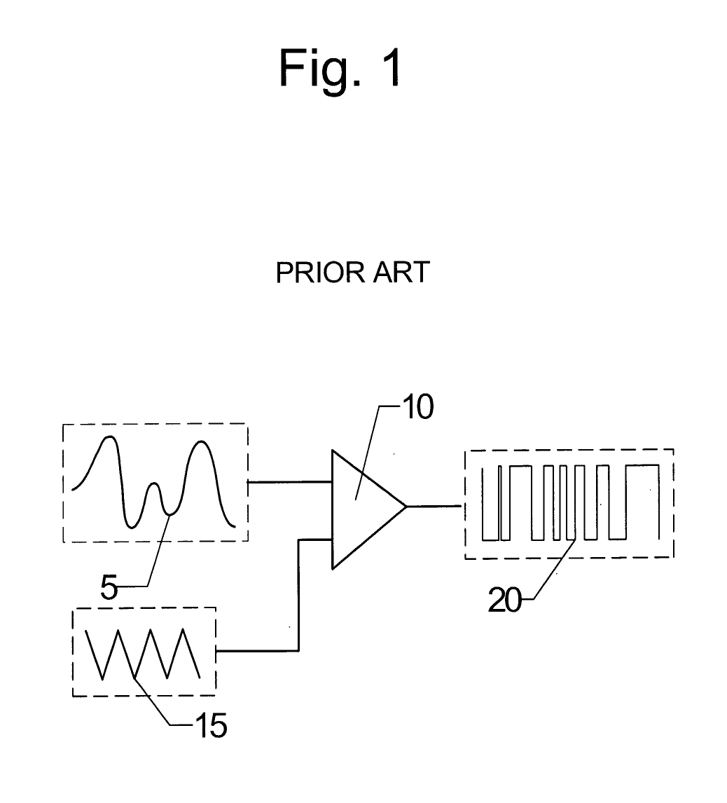

### DESCRIPTION FIGS. 1 to 9

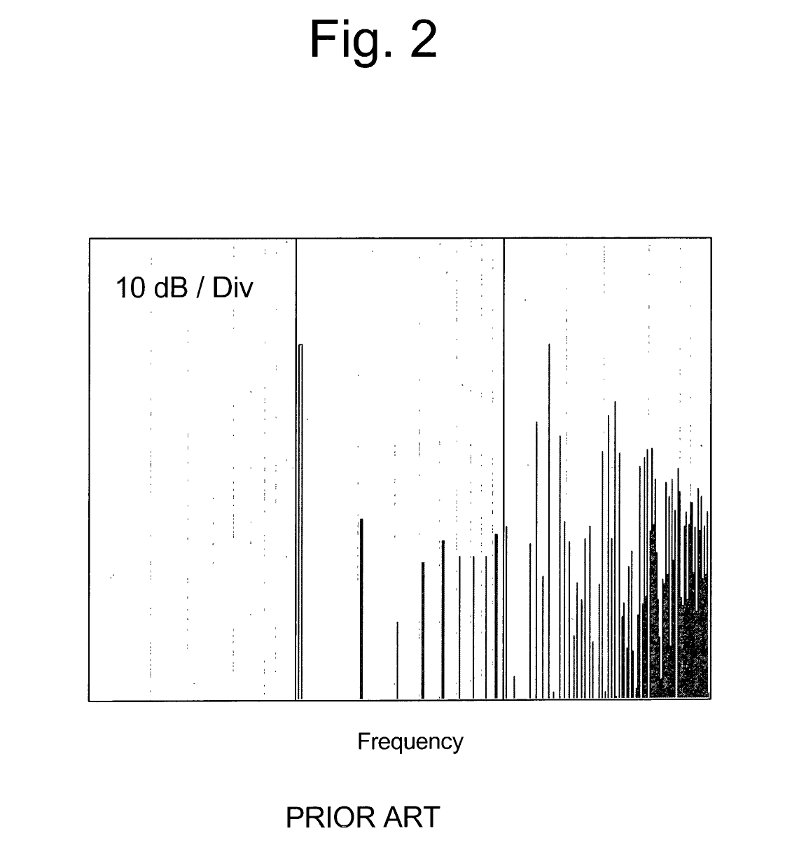

FIG. 1 shows a comparator means 10 with an input waveform 5, a comparison waveform 15 and an output signal 20, which is Pulse Width Modulated according to the input. The spectrum of the output signal is shown in FIG. 2.

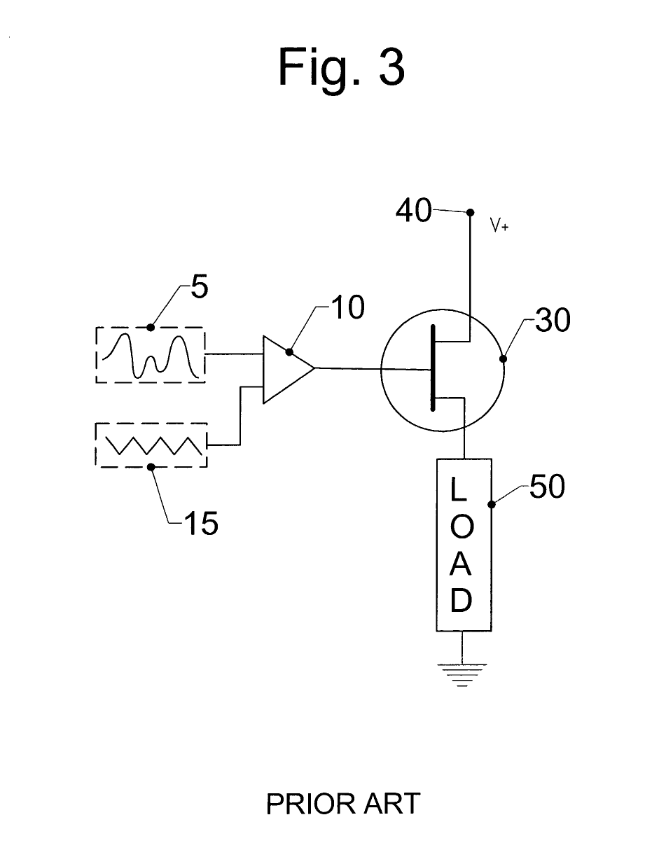

FIG. 3 shows an example of using a PWM signal to drive current through a load 50 from a voltage supply 40 in such a way as to dissipate little or no energy in the switching device 30.

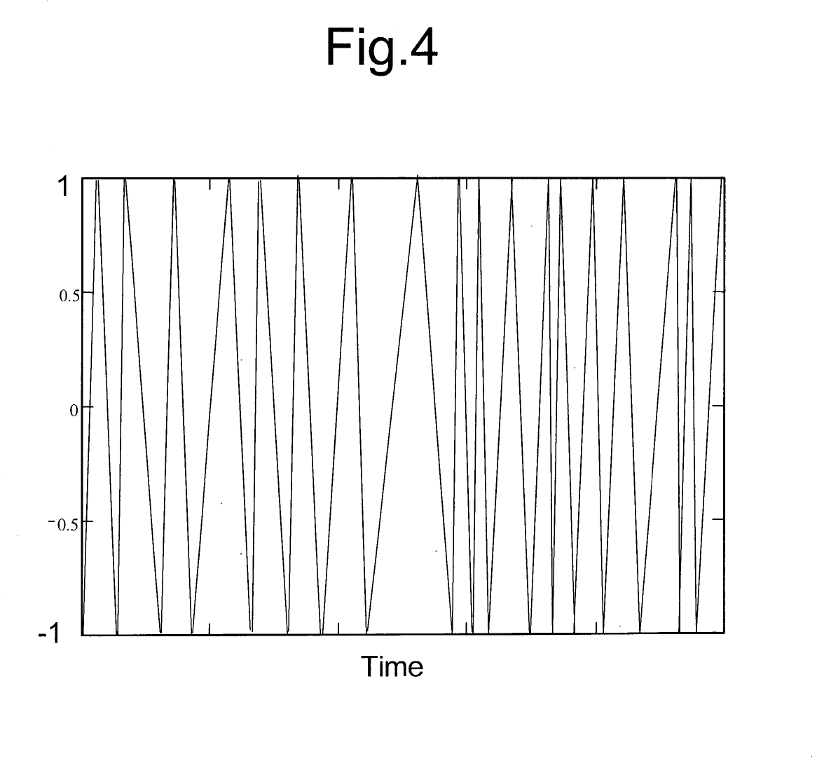

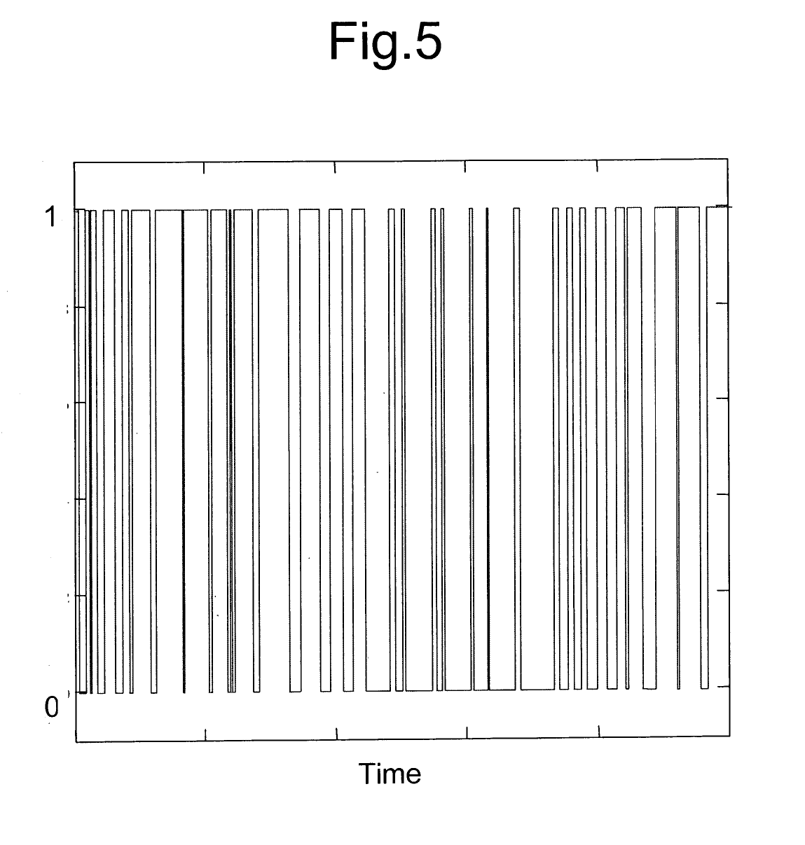

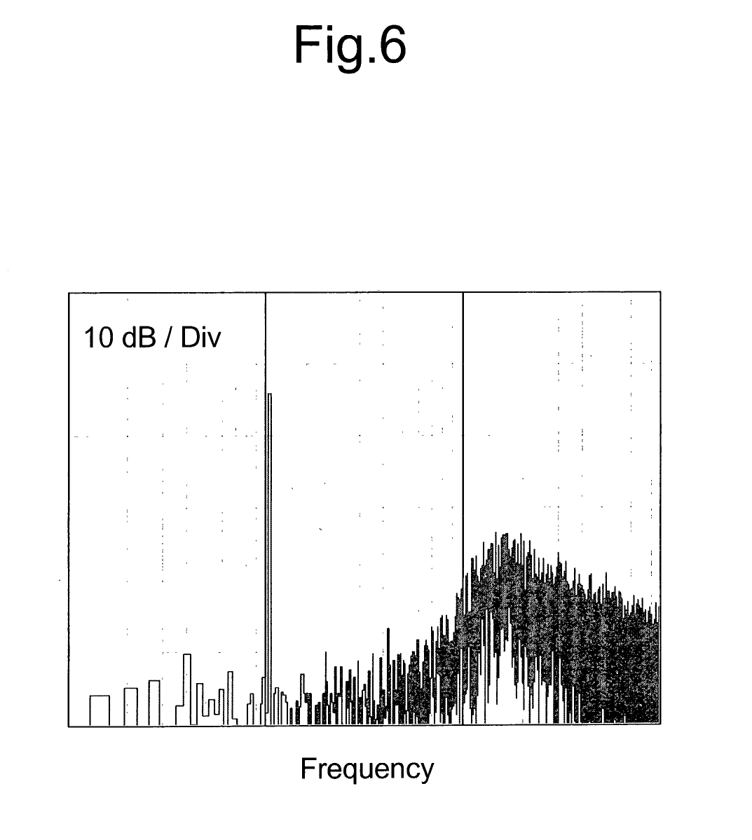

FIG. 4 shows an example of a random switching comparison waveform. When used as a comparison waveform in a circuit such as that shown in FIG. 3 the output signal will be generated as shown in FIG. 5. The spectrum of this output signal is shown in FIG. 6, which clearly demonstrates the improved nature of the PWM conversion when using this form of signal as the comparison waveform. The lower distortion and lower peak level of high frequency energy is evident in this figure.

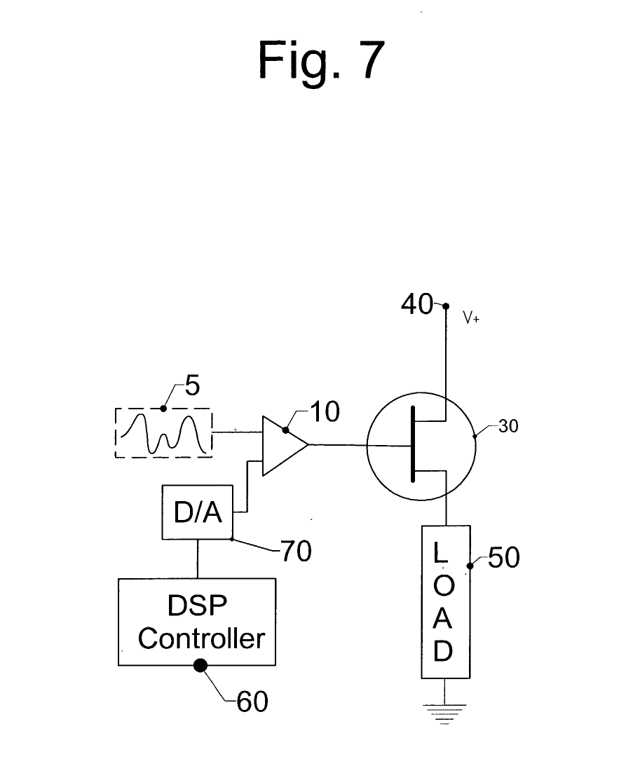

FIG. 7 shows a preferred embodiment wherein a DSP circuit 60 is used to generate the comparison waveform. A digital to analog converter 70 may be required to convert the DSP data into an analog signal for use by the comparator.

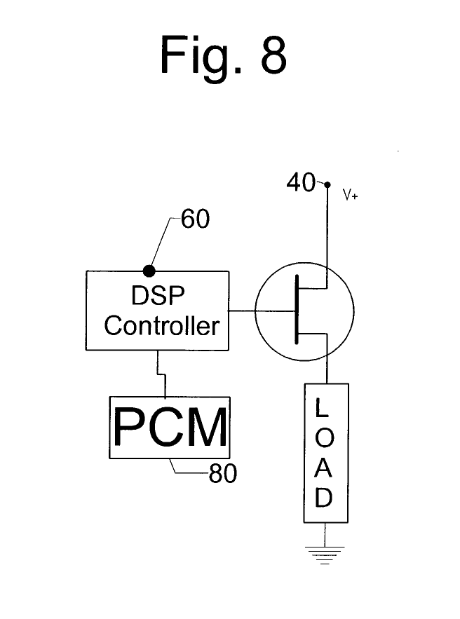

FIG. 8 shows another preferred embodiment wherein the comparator function is perform in code, within the DSP, using the same created comparison waveform as described above and a PCM input signal 80. This allows for a completely digital controller with no analog signals or paths at any point. Digital to analog and analog to digital converters can thus be eliminated. A digital input data stream can be amplified to any desired level and the final digital to analog conversion is achieved by simple lowpass filtering of the output waveform.

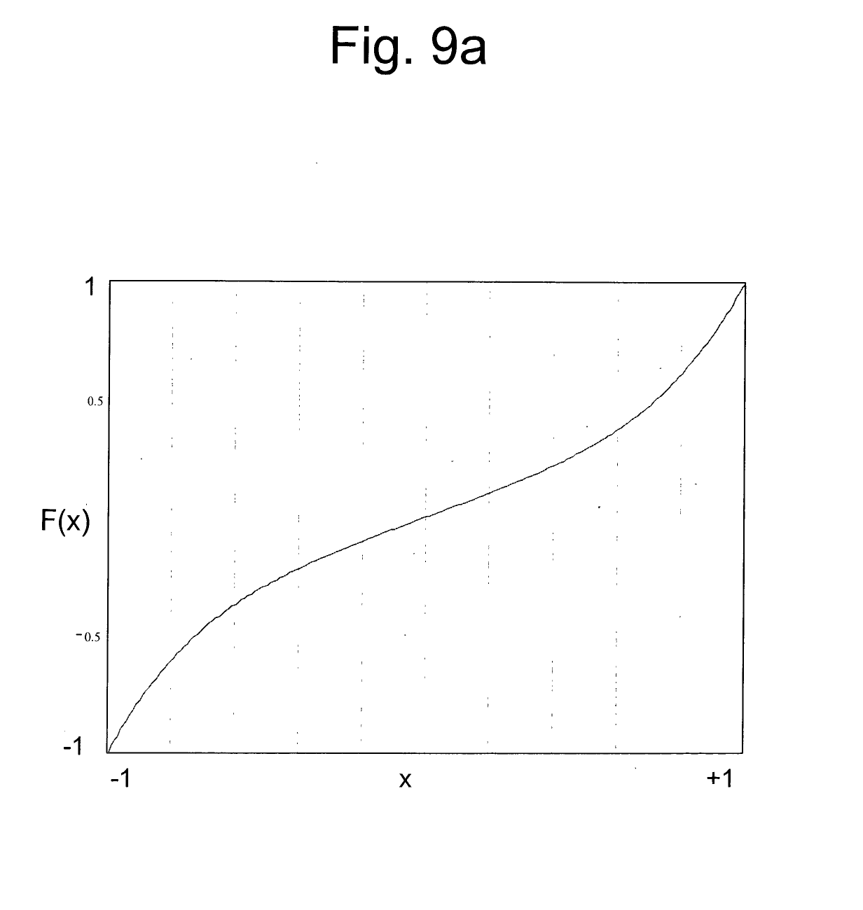

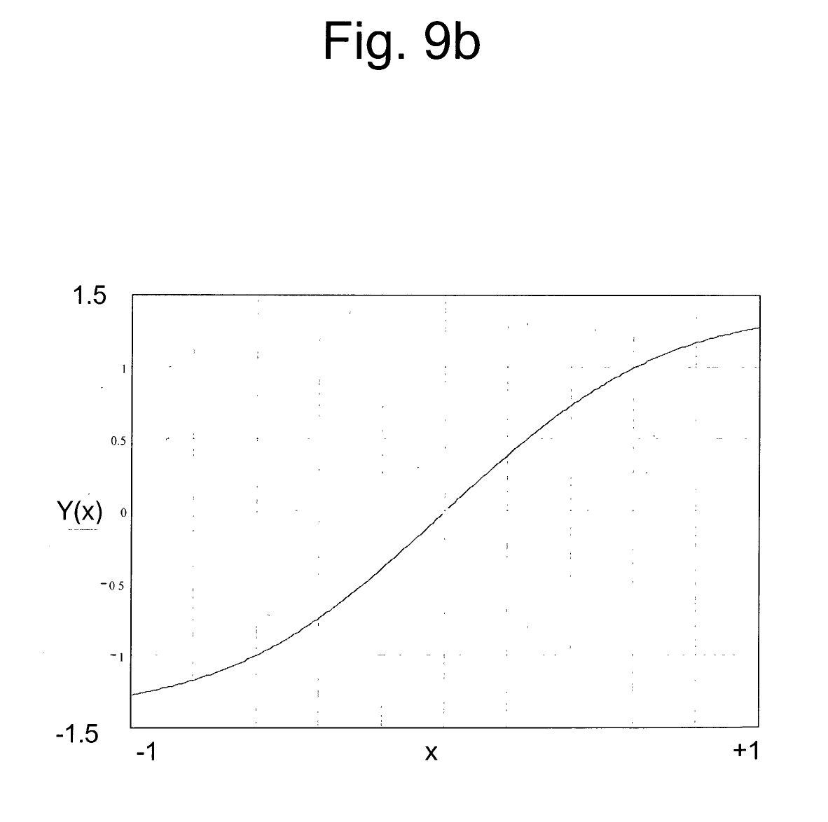

In a final preferred embodiment the comparator waveform is further modified by a multiplication factor F(x). An example of a usefulness of this multiplication factor is shown in FIG. 9a where a non-linear transfer function for the PWM conversion will be created as shown in FIG. 9b. This curve has the characteristic of a soft clipping that has been shown to be subjectively preferred to a hard clipping amplifier.

I claim as my invention:

1. A Pulse Width Modulator comprising:
a comparator means comprising;
an input signal; and
a comparison waveform which has straight lines toggling between two states in a fully random or a pseudo-random manner; wherein said pseudo-random signal is derived from a Maximum Length Sequence; and
an output waveform which is binary and represents a pulse width modulation of said input signal.

2. A Pulse Width Modulator as in claim 1 wherein:
said comparison waveform is created with a Digital Signal Processing means.

3. A Pulse Width Modulator as in claim 1 wherein:
said output waveform is connected to a power amplification means for driving a load.

4. A Pulse Width Modulator as in claim 2 wherein:
said output waveform is connected to a power amplification means for driving a load.

5. A Pulse Width Modulator as in claim 1 wherein:
said comparator means are perform in software code.

6. A Pulse Width Modulator as in claim 5 wherein:
said output waveform is connected to a power amplification means for driving a load.

6. A Pulse Width Modulator comprising:
a comparator means comprising;
an input signal; and
a comparison waveform which has straight lines toggling between two states in a random manner, said comparison waveform being further modified by a multiplicative factor, which depends on the instantaneous level of said comparison waveform, said comparison waveforms being modified by multiplying said comparison waveform by multiplying it by said multiplicative factor; and
an output waveform which is binary and represents a non-linear pulse width modulation of said input signal.

7. A Pulse Width Modulator as in claim 6 wherein:
said comparison waveform is created with a Digital Signal Processing means.

8. A Pulse Width Modulator as in claim 6 wherein:
said output waveform is connected to a power amplification means for driving a load.

9. A Pulse Width Modulator as in claim 7 wherein:
said output waveform is connected to a power amplification means for driving a load.

10. A Pulse Width Modulator as in claim 7 wherein:
said comparator means are perform in software code.
